(19) United States
(12) Patent Application Publication
(10) Pub. No.: US 2012/0061836 A1
(43) Pub. Date: Mar. 15, 2012

(54) SPRAY PYROLYSIS OF Y-DOPED ZnO

(75) Inventors: Lilly Q. Guo, Colleyville, TX (US); Meng Tao, Colleyville, TX (US); Kunhee Han, Flower Mound, TX (US)

(73) Assignee: TAO COMPANIES LLC, Colleyville, TX (US)

(21) Appl. No.: 12/883,170

(22) Filed: Sep. 15, 2010

(51) Int. Cl. H01L 23/532; B05D 5/12; H05K 1/09

(52) U.S. Cl. 257/741; 174/257; 427/126.3; 257/E23.155

(57) ABSTRACT

One example embodiment includes a method for applying a transparent conducting oxide. The method includes providing a solution, where the solution includes a solvent, a zinc precursor and an yttrium precursor. The method also includes spraying the solution on a heated substrate, where the heated substrate turns the solution into an yttrium-doped zinc oxide film. The method further includes annealing the film on the substrate in a controlled environment.

### CROSS-REFERENCE TO RELATED APPLICATIONS

Not applicable.

### BACKGROUND OF THE INVENTION

Transparent conducting oxides are used in a number of commercial applications. There are primarily two configurations in which transparent conducting oxides are employed: 1) a transparent conducting oxide film is deposited on a glass plate, and the coated glass is then used as a window with various functionalities such as antifogging and electromagnetic shielding; and 2) a transparent conducting oxide film is deposited on a semiconductor film in various electronic and optoelectronic devices such as flat-panel displays and photovoltaic solar cells.

The common transparent conducting oxides currently in commercial applications include: 1) tin-doped indium oxide by vacuum-based sputter deposition; 2) aluminum-doped zinc oxide by vacuum-based sputter deposition; and 3) fluorine-doped tin oxide by non-vacuum spray pyrolysis.

Tin-doped indium oxide by sputter deposition is widely regarded as the best performance transparent conducting oxide to date, because it displays the lowest resistivity, 1-3×10⁻⁴ Ω-cm, among all the current transparent conducting oxides. The low resistivity led to its dominance in the flat-panel display industry. The major drawback of tin-doped indium oxide is its high cost. There are two reasons for the high cost of tin-doped indium oxide. One is the vacuum-based deposition method. A large complex expensive vacuum system is required for sputter deposition. More importantly, the indium reserve in the Earth crust is very limited. Some estimates put the number at ˜20,000 metric tons in total indium reserve. With the short supply of indium and the rapid growth of the flat-panel industry, the price of indium has skyrocketed from as low as US$97/kg in 2002 to as high as US$918/kg in 2006. The short supply of indium is only going to get worse, as the solar cell industry rapidly expands.

Aluminum-doped zinc oxide can be employed as an alternative to tin-doped indium oxide. All the source materials in aluminum-doped zinc oxide, aluminum, zinc and oxygen, are abundant and their reserves are more than enough for all foreseeable applications. The major drawback of aluminum-doped zinc oxide is its high cost, primarily due to the complex expensive vacuum system for its sputter deposition. In addition, the resistivity of aluminum-doped zinc oxide is higher than that of tin-doped indium oxide.

Fluorine-doped tin oxide is another common transparent conducting oxide. Among the source materials for fluorine-doped tin oxide, fluorine and oxygen are very abundant and tin is reasonably abundant. Fluorine-doped tin oxide has a lower cost than the two transparent conducting oxides discussed above for two reasons. One is the abundance of its source materials. The second reason is its deposition is wet-chemistry based, which does not require a vacuum system. The major drawbacks for fluorine-doped tin oxide are: 1) the temperature for its deposition is typically ˜450° C. This temperature is higher than the temperature at which many semiconductor films are prepared. If fluorine-doped tin oxide is deposited on such a semiconductor film, the semiconductor is likely to be damaged by the high temperature. For this reason, fluorine-doped tin oxide is typically deposited on glass; and 2) the resistivity of fluorine-doped tin oxide is higher than that of tin-doped indium oxide, typically above 5×10⁻⁴ Ω-cm.

One possibility to obtain a low-cost high-performance transparent conducting oxide is wet-chemistry based deposition of aluminum-doped zinc oxide. Unfortunately, the resistivity of non-vacuum prepared aluminum-doped zinc oxide tends to be much higher towards 1×10⁻³ Ω-cm. Alternatively, one can try to find another dopant for wet-chemistry deposited zinc oxide. As an example, indium can be used as a dopant in wet-chemistry deposited zinc oxide. A solution containing zinc acetate and indium chloride (InCl₃) is sprayed onto a heated substrate at 400° C. The lowest resistivity achieved is 4×10⁻⁵ Ω-cm. However, indium is a scarce and expensive material. The ideal dopant needs to be low cost, abundant, and at the same time provides low-resistivity and high-transmissivity zinc oxide.

Yttrium-doped zinc oxide by electrochemical deposition has demonstrated a low resistivity down to 6.3×10⁻⁵ Ω-cm, and 2×10⁻⁴ Ω-cm can be reproducibly achieved in yttrium-doped zinc oxide by electrochemical deposition. Yttrium does satisfy all the requirements as an ideal dopant for zinc oxide: it is abundant with total reserve of more than 600,000 metric tons, it is low cost, and it produces low-resistivity and high-transmissivity zinc oxide. However, electrochemical deposition has several major limitations for commercial applications: 1) electrochemical deposition requires a conducting substrate, which prevents it from being applied to glass substrate; and 2) when electrochemical deposition is applied on large-area semiconductor films, the deposited transparent conducting oxide film usually suffers from thickness nonuniformity.

For these reasons, there is a need in the art for a new wet-chemistry based deposition method for yttrium-doped zinc oxide. Additionally, the method must not be based on the use of expensive vacuum technology. Further, the method must reliably produce the yttrium-doped zinc oxide film with a uniform thickness. In addition, the deposition method must be suitable for use on non-metallic substrates such as semiconductors and glass.

### BRIEF SUMMARY OF SOME EXAMPLE EMBODIMENTS

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

One example embodiment includes a method for applying a transparent conducting oxide. The method includes providing a solution, where the solution includes a solvent, a zinc precursor and an yttrium precursor. The method also includes spraying the solution on a heated substrate, where the heated substrate turns the solution into an yttrium-doped zinc oxide film. The method further includes annealing the film on the substrate in a controlled environment.

Another example embodiment includes a method for applying a transparent conducting oxide. The method includes providing a solution, where the solution includes a solvent, a zinc precursor and an yttrium precursor. The method also includes providing a heated substrate, where the substrate includes a base layer to which a transparent conducting oxide can be applied. The method further includes spraying the solution on the heated substrate, where spraying the solution on the substrate includes providing a carrier gas, pressurizing the carrier gas and spraying the pressurized carrier gas and the solution onto the substrate, where the carrier gas atomizes the solution. The heated substrate turns the solution into an yttrium-doped zinc oxide film. The method also includes annealing the film on the substrate in a controlled environment.

Another example embodiment includes a structure. The structure includes a substrate, where the substrate includes a base layer to which a transparent conducting oxide can be applied. The structure also includes the transparent conducting oxide, where the transparent conducting oxide includes a zinc oxide layer and an yttrium oxide dopant, where the yttrium oxide dopant is within the zinc oxide layer.

These and other objects and features of the present invention will become more fully apparent from the following description and appended claims, or may be learned by the practice of the invention as set forth hereinafter.

### BRIEF DESCRIPTION OF THE DRAWINGS

To further clarify various aspects of some example embodiments of the present invention, a more particular description of the invention will be rendered by reference to specific embodiments thereof which are illustrated in the appended drawings. It is appreciated that these drawings depict only illustrated embodiments of the invention and are therefore not to be considered limiting of its scope. The invention will be described and explained with additional specificity and detail through the use of the accompanying drawings in which:

FIG. 1 illustrates an example of a structure;

FIG. 2 illustrates an example of a photovoltaic cell;

FIG. 3 illustrates a system for spraying a solution on a substrate; and

FIG. 4 is a flow chart illustrating a method of producing a transparent conducting oxide.

### DETAILED DESCRIPTION OF SOME EXAMPLE EMBODIMENTS

Reference will now be made to the figures wherein like structures will be provided with like reference designations. It is understood that the figures are diagrammatic and schematic representations of some embodiments of the invention, and are not limiting of the present invention, nor are they necessarily drawn to scale.

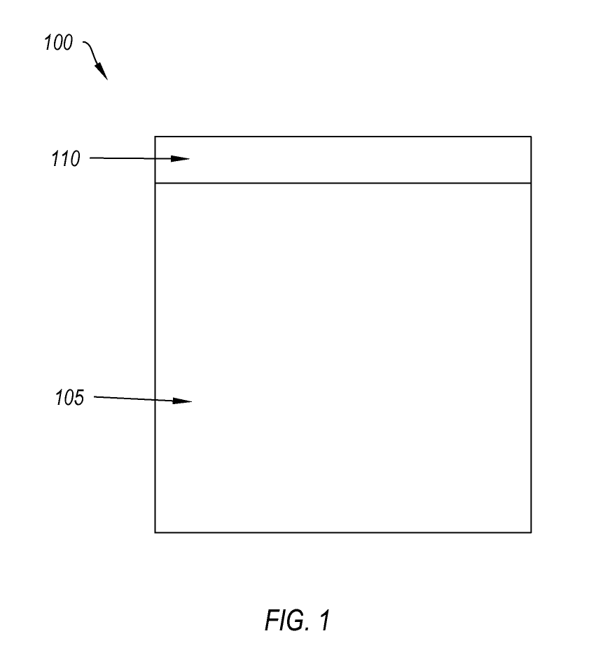

FIG. 1 illustrates an example of a structure 100. In at least one implementation, the structure 100 can be used for electromagnetic shielding, used as part of a photovoltaic cell, used for defogging, used in a flat panel display or for any other use. The structure 100 can be connected to an external voltage in order to produce electromagnetic radiation or heat. Additionally or alternatively, the structure 100 can be used to convert electromagnetic radiation into electrical power.

FIG. 1 shows that the structure 100 includes a substrate 105. In at least one implementation, the substrate 105 includes a base layer of material. For example, the substrate 105 could be a glass plate. Additionally or alternatively, the substrate 105 could include a semiconductor or other electronic device. For example, the substrate 105 could include a semiconductor that forms a portion of a photovoltaic cell for producing electricity from electromagnetic radiation.

FIG. 1 also shows that the structure 100 can include a transparent conducting oxide 110. In at least one implementation, the transparent conducting oxide 110 includes materials that act both as a window for light to pass through to the substrate 105 beneath and as an electrical contact for carrier transport out of the structure 100. In particular, the transparent conducting oxide 110 can possess bandgaps with energies corresponding to wavelengths which are shorter than the visible range (380 nm to 750 nm). As such, photons with energies below the bandgap are not collected by the transparent conducting oxide 110 and thus visible light passes through the transparent conducting oxide 110. Additionally or alternatively, the transparent conducting oxide 110 can have a broader bandgap to avoid unwanted absorption of incident electromagnetic radiation.

In at least one implementation, the transparent conducting oxide 110 can be a thin layer. If the transparent conducting oxide 110 is thin, more light can pass through the transparent conducting oxide 110 to the layers beneath. For example, the transparent conducting oxide 110 can be between 100 nanometers and 10 micrometers thick. In particular, the transparent conducting oxide 110 can be approximately 500 nanometers thick. As used in the specification and the claims, the term approximately shall mean that the value is within 10% of the stated value, unless otherwise specified.

In at least one implementation, the transparent conducting oxide 110 will have a resistivity. Electrical resistivity (also known as specific electrical resistance or volume resistivity) is a measure of how strongly a material opposes the flow of electric current. A low resistivity indicates a material that readily allows the movement of electrical charge. Electrical resistivity can be measured as ohm meters (Ω-m) or as ohm centimeters (Ω-cm) where 1 Ω-m=100 Ω-cm.

In at least one implementation, the transparent conducting oxide 110 will have a low resistivity. For example, the transparent conducting oxide 110 can have a resistivity below 5×10⁻⁴ Ω-cm. In particular, the transparent conducting oxide 110 can have a resistivity between 1×10⁻⁴ Ω-cm and 3×10⁻⁴ Ω-cm. Moreover, the transparent conducting oxide can have a resistivity of approximately 2×10⁻⁴ Ω-cm.

In at least one implementation, the transparent conducting oxide 110 can include zinc oxide. Zinc oxide is an inorganic compound with the formula ZnO. It usually appears as a white powder, nearly insoluble in water. In at least one implementation, one or more zinc precursors can be applied to the substrate 105 and then allowed to oxidize, as described below. For example, zinc precursors could include zinc chloride (ZnCl₂), zinc acetate (Zn(CH₃CO₂)₂), zinc nitrate (Zn(NO₃)₂), zinc sulfate (ZnSO₄) or any other zinc compound that will dissolve in the chosen solvent.

In at least one implementation, the transparent conducting oxide 110 can include an yttrium oxide dopant. Yttrium oxide is an inorganic compound with the formula Y₂O₃. It usually appears as a white powder, nearly insoluble in water. In at least one implementation, one or more yttrium precursors can be applied to the substrate 105 and then allowed to oxidize, as described below. For example, yttrium precursors could include yttrium chloride (YCl₃), yttrium acetate (Y(CH₃CO₂)₃), yttrium nitrate (Y(NO₃)₃), yttrium sulfate (Y₂(SO₄)₃) or any other yttrium compound that will dissolve in the chosen solvent.

A dopant, also called a doping agent, is a trace impurity element that is inserted into a substance (sometimes in very low concentrations) in order to alter the electrical properties or the optical properties of the substance. In the case of crystalline substances, the atoms of the dopant very commonly take the place of elements that were in the crystal lattice of the material. The addition of a dopant to a semiconductor, known as doping, has the effect of shifting the Fermi level within the material. This results in a material with predominantly negative (n-type) or positive (p-type) charge carriers depending on the dopant variety.

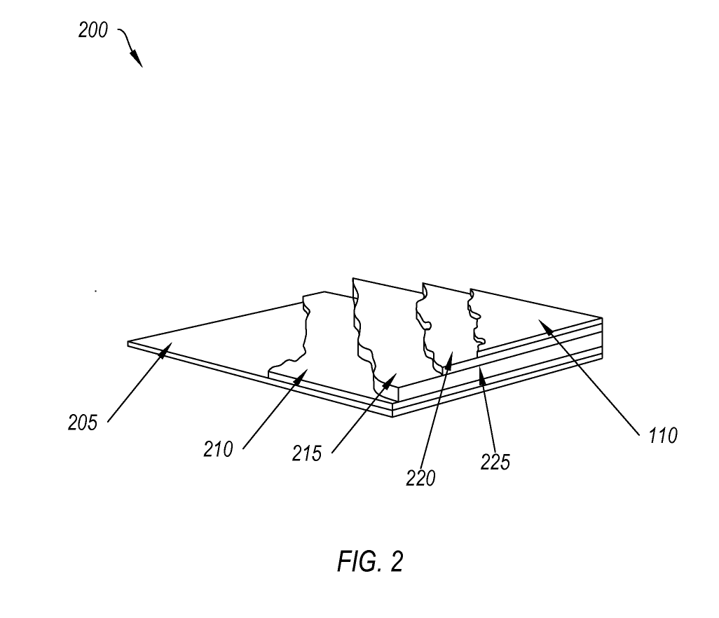

FIG. 2 illustrates an example of a photovoltaic cell 200. In at least one implementation, a photovoltaic cell 200 is a solid state device that uses the photovoltaic effect to generate electrical energy using the potential difference that arises between materials when the surface of the cell is exposed to electromagnetic radiation. A photovoltaic cell is commonly used for detecting radiation (e.g., infrared detectors), measurement of light intensity (e.g., measuring optical density), chemical processes (e.g., spectrophotometry), and for conversion of light energy to electricity in conversion photovoltaic cells. In at least one implementation, the photovoltaic cell 200 can be used to convert solar radiation (e.g., as a solar cell).

In at least one implementation, the photovoltaic effect involves the creation of a voltage (or a corresponding electric current) in a material upon exposure to electromagnetic radiation. The photovoltaic effect includes generating electrons that are transferred from different bands (i.e. from the valence to conduction bands) within the material, resulting in the buildup of a voltage between two electrodes. In the case of a p-n junction solar cell, illumination of the material results in the creation of an electric current as excited electrons and the remaining holes are swept in different directions by the built-in electric field of the depletion region, as described below.

FIG. 2 shows that the photovoltaic cell 200 can include a substrate 205. In at least one implementation, a substrate 205 includes a base layer of material on which the photovoltaic cell 200 is produced. For example, the substrate 205 could be a glass plate onto which other layers of the photovoltaic cell 200 are laid, as described below. The substrate 205 can be removed after other layers have been added or can be left in order to protect the photovoltaic cell 200.

FIG. 2 also shows that the photovoltaic cell 200 can include an electrical contact 210. In at least one implementation, an electrical contact 210 is a region on a semiconductor device that has been prepared so that the resistance for an electrical current to flow through it is small. For example, the electrical contact 210 can include sputtered or evaporated metal pads that are patterned using photolithography. The electrical contract 210 can also include a spray-deposited transparent conducting oxide film which provides low-resistance, transparent contacts.

FIG. 2 further shows that the photovoltaic cell 200 can include a p-type semiconductor 215. In at least one implementation, a p-type semiconductor 215 is obtained by carrying out a process of doping, that is adding a certain type of atoms to the semiconductor in order to increase the number of free charge carriers (in this case positive). When the doping material is added, it takes away (accepts) outer electrons from the semiconductor atoms. This type of doping agent is also known as an acceptor material and the vacancy left behind by the electron is known as a hole.

The purpose of p-type doping is to create an abundance of holes. In the case of silicon, a trivalent atom (typically from group IIIA of the periodic table, such as boron or aluminum) is substituted into the crystal lattice. The result is that one electron is missing from one of the four covalent bonds normal for the silicon lattice. Thus the dopant atom can accept an electron from a neighboring atom's covalent bond to complete the fourth bond. This is why such dopants are called acceptors. The dopant atom accepts an electron, causing the loss of half of one bond from the neighboring atom and resulting in the formation of a “hole”. Each hole is associated with a nearby negatively-charged dopant ion, and the semiconductor remains electrically neutral as a whole. However, once each hole has wandered away into the lattice, one proton in the atom at the hole's location will be “exposed” and no longer cancelled by an electron. For this reason a hole behaves as a quantity of positive charge. When a sufficiently large number of acceptor atoms are added, the holes greatly outnumber the thermally-excited electrons. Thus, the holes are the majority carriers, while electrons are the minority carriers in the p-type semiconductor 215. Therefore, to a first approximation, a sufficiently doped p-type semiconductor 215 can be thought of as only conducting holes.

FIG. 2 also shows that the photovoltaic cell 200 can include an n-type semiconductor 220. In at least one implementation, the n-type semiconductor 220 can include a type of semiconductor where the dopant atoms are capable of providing extra conduction electrons to the host material (e.g. phosphorus in silicon). This creates an excess of negative electron charge carriers in the n-type semiconductor 220.

FIG. 2 further shows that where the p-type semiconductor 215 meets the n-type semiconductor 220 a p-n junction 225 is formed at the interface. In at least one implementation, the p-type semiconductor 215, the n-type semiconductor 220 and the p-n junction 225 can be formed in a single crystal of semiconductor by doping; for example, by ion implantation, diffusion of dopants, or by epitaxy (growing a layer of crystal doped with one type of dopant on top of a layer of crystal doped with another type of dopant).

In a least one implementation, the p-n junction 225 can be used in the formation of electronic devices. In particular, the p-type semiconductor 215 is relatively conductive and the n-type semiconductor 220 is relatively conductive, however the p-n junction 225 between them is a nonconductor. This nonconducting layer, called the depletion zone, occurs because the electrical charge carriers in doped n-type semiconductor 220 and p-type semiconductor 215 (electrons and holes, respectively) diffuse into the other type of material (i.e. electrons into the p-type semiconductor 215 and holes into the n-type semiconductor 220) and eliminate each other in a process called recombination. By manipulating this non-conductive layer, the p-n junction 225 can be used as a diode. I.e., the p-n junction 225 can allow a flow of electricity in one direction but not in the other (opposite) direction. This property is explained in terms of forward bias and reverse bias, where the term bias refers to an application of electric voltage to the p-n junction 225.

Without an applied bias, the p-n junction 225 reaches an equilibrium condition in which a potential difference is formed across the junction. This potential difference is called built-in potential Vbi. After joining the p-type semiconductor 215 and n-type semiconductor 220, electrons near the p-n junction 225 tend to diffuse into the p-type semiconductor 215. As electrons diffuse, they leave positively charged ions (donors) in the n-type semiconductor 220. Similarly, holes near the p-n junction 225 begin to diffuse into the n-type semiconductor 220 leaving fixed ions (acceptors) with negative charge. The regions nearby the p-n junction 225 lose their neutrality and become charged, forming the depletion layer. The electric field created by the space charge region opposes the diffusion process for both electrons and holes. Thus, there are two concurrent phenomena: the diffusion process that tends to generate more space charge and the electric field generated by the space charge that tends to counteract the diffusion.

In forward bias, the p-type semiconductor 215 is connected with the positive terminal of a voltage source and the n-type semiconductor 220 is connected with the negative terminal. Connected this way, the holes in the p-type semiconductor 215 and the electrons in the n-type semiconductor 220 are pushed towards the p-n junction 225. This reduces the width of the depletion zone. The positive charge applied to the p-type semiconductor 215 repels the holes, while the negative charge applied to the n-type semiconductor 220 repels the electrons. As electrons and holes are pushed towards the junction, the distance between them decreases. This lowers the barrier in potential. With increasing forward-bias voltage, the depletion zone eventually becomes thin enough that the zone's electric field cannot counteract charge carrier motion across the p-n junction 225, consequently reducing electrical resistance. The electrons which cross the p-n junction 225 into the p-type semiconductor 215 (or holes which cross into the n-type semiconductor 220) will diffuse in the near-neutral region. Therefore, the amount of minority diffusion in the near-neutral zones determines the amount of current that may flow through the diode.

Only majority carriers can flow through a semiconductor for a macroscopic length. The forward bias causes a force on the electrons pushing them from the n-type semiconductor 220 toward the p-type semiconductor 215. With forward bias, the depletion region is narrow enough that electrons can cross the p-n junction 225 and inject into the p-type semiconductor 215. However, they do not continue to flow through the p-type semiconductor 215 indefinitely, because it is energetically favorable for them to recombine with holes. Although the electrons penetrate only a short distance into the p-type semiconductor 215, the electric current continues uninterrupted, because holes (the majority carriers) begin to flow in the opposite direction. The flow of holes from the p-type semiconductor 215 into the n-type semiconductor 220 is exactly analogous to the flow of electrons from the n-type semiconductor 220 to the p-type semiconductor 215 (electrons and holes swap roles and the signs of all currents and voltages are reversed).

Therefore, the macroscopic picture of the current flow through the p-n junction 225 involves electrons flowing through the n-type semiconductor 220 toward the p-n junction 225, holes flowing through the p-type semiconductor 215 in the opposite direction toward the p-n junction 225, and the two species of carriers constantly recombining in the vicinity of the p-n junction 225. The electrons and holes travel in opposite directions, but they also have opposite charges, so the overall current is in the same direction on both sides of the p-n junction 225.

In reverse bias the p-type semiconductor 215 is connected with the negative terminal of a voltage source and the n-type semiconductor 220 is connected with the positive terminal. Therefore, no current will flow until the diode breaks down. Because the p-type semiconductor 215 is now connected to the negative terminal of the power supply, the holes in the p-type semiconductor 215 are pulled away from the p-n junction 225, causing the width of the depletion zone to increase. Similarly, because the n-type semiconductor 220 is connected to the positive terminal, the electrons will also be pulled away from the p-n junction 225. Therefore the depletion region widens, and does so increasingly with increasing reverse-bias voltage. This increases the voltage barrier causing a high resistance to the flow of charge carriers thus allowing minimal electric current to cross the p-n junction 225.

In at least one implementation, when electromagnetic radiation strikes the photovoltaic cell 200, the photons are absorbed by the photovoltaic cell 200. Electrons are knocked loose from their atoms, allowing them to flow through the material to produce electricity. In particular, the electrons are only allowed to move in a single direction within the photovoltaic cell 200 because of the p-n junction 225, as described above. In at least one implementation, when a photon is absorbed, its energy is given to an electron in the crystal lattice. Usually this electron is in the valence band, and is tightly bound in covalent bonds between neighboring atoms, and hence unable to move far. The energy given to it by the photon “excites” it into the conduction band, where it is free to move around within the semiconductor. The covalent bond that the electron was previously a part of now has one fewer electron forming a hole. The presence of a missing covalent bond allows the bonded electrons of neighboring atoms to move into the hole leaving another hole behind, and in this way a hole can move through the lattice. Thus, it can be said that photons absorbed in the semiconductor create mobile electron-hole pairs.

In at least one implementation, the hole-electron pair becomes separated. In particular, there are two main modes for charge carrier separation in a solar cell. The carriers can drift, i.e., be driven by an electrostatic field established across the device. Additionally or alternatively, the carriers can diffuse from zones of high carrier concentration to zones of low carrier concentration (following a gradient of electrochemical potential).

The light-induced charge separation creates a reverse current through the p-n junction 225 (that is, not in the direction that a diode normally conducts current), and the charge separation causes a photo voltage that drives current through any attached load. However, a side effect of this voltage is that it tends to forward bias the junction. At high enough levels, this forward bias of the junction will cause a forward current in the diode that subtracts from the current created by the light. Consequently, the greatest current is obtained under short-circuit conditions.

The diode possesses a built-in potential due to the contact potential difference between the p-type semiconductor 215 and n-type semiconductor 220 on either side of the p-n junction 225, as discussed above. This built-in potential is established when the p-n junction 225 is formed as a by-product of thermodynamic equilibrium. Once established, this potential difference cannot drive a current; however, as connecting a load does not upset this equilibrium. In contrast, the accumulation of excess electrons in one region and of excess holes in another due to illumination results in a photo voltage that does drive a current when a load is attached to the illuminated p-n junction 225. As noted above, this photo voltage also forward biases the junction, and so reduces the pre-existing field in the depletion region.

FIG. 2 also shows that the photovoltaic cell 200 can include a transparent conducting oxide 110. In at least one implementation, the transparent conducting oxide 110 includes materials that act both as a window for light to pass through to the layers beneath and as an electrical contact for carrier transport out of the photovoltaic cell 200. In particular, the transparent conducting oxide 110 can possess bandgaps with energies corresponding to wavelengths which are shorter than the visible range (380 nm to 750 nm). As such, photons with energies below the bandgap are not collected by the transparent conducting oxide 110 and thus visible light passes through the transparent conducting oxide 110. Additionally or alternatively, the transparent conducting oxide 110 can have a broader bandgap to avoid unwanted absorption of incident electromagnetic radiation.

In at least one implementation, the photovoltaic cell 200 can include an anti-reflection coating. The anti-reflection coating can allow electromagnetic radiation to enter the photovoltaic cell 200 and direct electromagnetic radiation that is reflecting from lower layers of the photovoltaic cell 200 back into the photovoltaic cell 200. This can increase the absorption of electromagnetic radiation within the photovoltaic cell 200, thus increasing the current produced by the photovoltaic cell 200. The transparent conducting oxide 110 can serve as an electrical contact and an anti-reflection coating or an additional anti-reflection coating can be added to the top of the transparent conducting oxide 110.

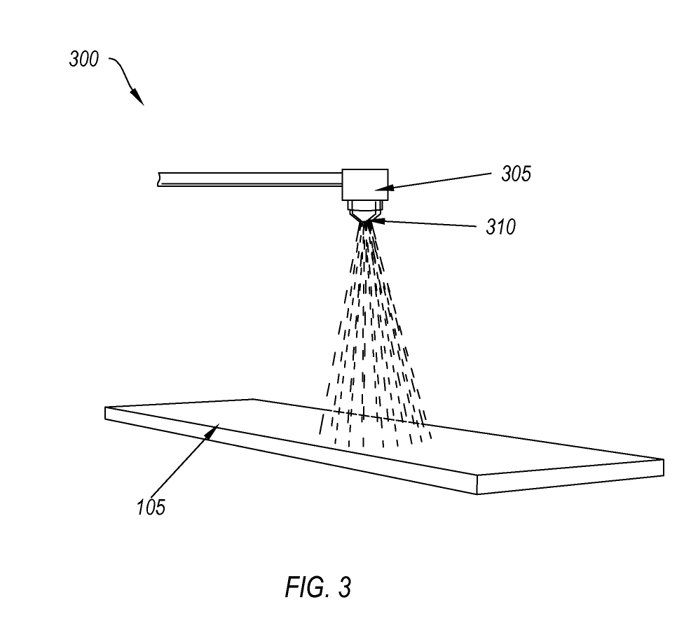

FIG. 3 illustrates a system 300 for spraying a solution onto a substrate 105. In at least one implementation, the solution can include a zinc precursor and an yttrium precursor. The substrate 105 is heated. When the solution is sprayed onto the heated substrate, the zinc precursor and the yttrium precursor can be oxidized to form a film of zinc oxide doped with yttrium oxide. Additionally or alternatively, the system 300 can be used for forming a film of a transparent conducting oxide other than yttrium-doped zinc oxide.

FIG. 3 shows that the system 300 includes a sprayer 305. In at least one implementation, the sprayer 305 pushes a carrier gas and a solution through a nozzle 310. The carrier gas atomizes the solution as the carrier gas and solution pass through the nozzle 310. Atomizing the solution includes reducing the solution to fine particles or mist that then adheres to the surface of the heated substrate 105. By spraying a small amount of solution on the surface of the substrate, the transparent conducting oxide can be thin. For example, the resultant transparent conducting oxide can be between 100 nanometers and 10 micrometers thick. In particular, a transparent conducting oxide can be produced that is approximately 500 nanometers thick.

In at least one implementation, the flow rate of the carrier gas and the solution through the nozzle 310 can be adjusted as desired. For example, the flow rate of the carrier gas can be changed to modify the size of the solution droplets formed during application.

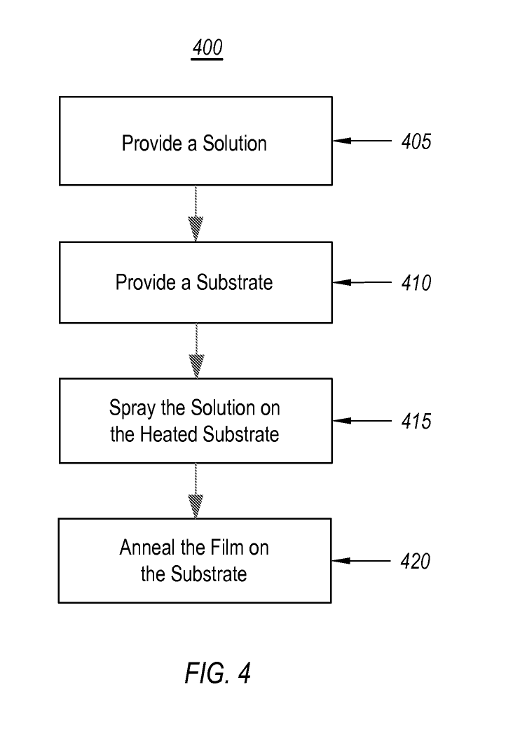

FIG. 4 is a flow chart illustrating a method 400 of producing a transparent conducting oxide. One of skill in the art will appreciate that the method 400 can be used to produce the transparent conducting oxide 110 of FIG. 1; however, the method 400 can be used to produce a transparent conducting oxide other than the transparent conducting oxide 110 of FIG. 1.

FIG. 4 shows that the method 400 includes providing a solution 405. In at least one implementation, a solution includes a homogeneous, ionic/molecular mixture of two or more substances. In particular, a solution is a mixture of one or more liquids. For example, the solution can include a solvent. In at least one implementation, a solvent includes a substance that dissolves another to form a solution. For example, the solvent can be aqueous or organic. Some examples of organic solvent include methanol (CH₃OH), acetone (CH₃COCH₃), or toluene (C₆H₅CH₃).

In at least one implementation, the solution can also include a zinc precursor. In particular, the zinc precursor can be any substance which is configured to be applied to a substrate and then allowed to oxidize. For example, zinc precursors could include zinc chloride (ZnCl₂), zinc acetate (Zn(CH₃CO₂)₂), zinc nitrate (Zn(NO₃)₂), zinc sulfate (ZnSO₄) or any other zinc compound that will dissolve in the chosen solvent. The concentration of the zinc precursor in the solution can be configured to provide a zinc oxide layer of the desired thickness. For example, the concentration of the zinc precursor could be between 10 mM and 10 M.

In at least one implementation the solution can also include an yttrium precursor. In particular, the yttrium precursor can be any substance which is configured to be applied to a substrate and then allowed to oxidize to form yttrium oxide. For example, yttrium precursors could include yttrium chloride (YCl₃), yttrium acetate (Y(CH₃CO₂)₃), yttrium nitrate (Y(NO₃)₃), yttrium sulfate (Y₂(SO₄)₃) or any other yttrium compound that will dissolve in the chosen solvent. The concentration of the yttrium precursor in the solution can be configured to provide yttrium oxide dopant in the desired ratio to zinc oxide. For example, the concentration of the yttrium precursor could be between 0.1 percent and 15 percent of the concentration of the zinc precursor. In particular, the concentration of the yttrium precursor could be approximately 8 percent of the concentration of the zinc precursor. E.g., the concentration of the yttrium precursor could be between 1 mM and 1 M if the concentration of the zinc precursor is between 10 mM and 10 M.

In at least one implementation, other chemicals can be added to the solution at different concentrations for various purposes. These additives can be acids, bases, salts, organics, or any combination thereof. Their concentrations individually or collectively can be within 1 to 100 percent of the concentration of the zinc precursor. The additives can be used, for example, to improve film adhesion, reduce film porosity, or reduce pyrolysis temperature.

FIG. 4 also shows that the method 400 includes providing a substrate 410. In at least one implementation, the substrate includes a base layer of material. For example, the substrate could be a glass plate. Additionally or alternatively, the substrate could include a semiconductor or other electronic device. For example, the substrate could include a photovoltaic cell for producing electricity from electromagnetic radiation. One of skill in the art will appreciate that the substrate can be provided for creating subsequent layers and then removed or can remain as part of the final device.

FIG. 4 further shows that the method 400 includes spraying the solution on the heated substrate 415. In at least one implementation, spraying the solution on the heated substrate 415 includes providing a uniform amount of solution on the substrate. The uniform solution can then produce a uniform film of transparent conducting oxide, as described below.

In at least one implementation, spraying the solution on the heated substrate 415 includes providing a carrier gas. The carrier gas can either contain oxygen or can be oxygen free. For example, air, oxygen, or water-saturated nitrogen can be used as a carrier gas that contains oxygen. Additionally or alternatively, nitrogen or helium can be used as a carrier gas that does not contain oxygen. Using oxygen in the carrier gas can allow the zinc precursor and the yttrium precursor to oxidize during the spraying process. In contrast, using a carrier gas that does not contain oxygen can allow the zinc precursor and the yttrium precursor to be oxidized by the air.

In at least one implementation, spraying the solution on the heated substrate 415 also includes pressurizing the carrier gas. For example, the pressure of the carrier gas can vary between 5 and 40 psi. In particular, the pressure of the carrier gas can be approximately 10 psi. Pressurizing the carrier gas can allow the carrier gas to atomize the solution during the spraying process. The flow rate of the carrier gas can vary between 1 and 500 L per minute.

In at least one implementation, the substrate can be heated before the solution is sprayed on the substrate. In particular, the substrate can be heated to cause pyrolysis of the zinc precursor and the yttrium precursor. Pyrolysis is the application of heat to chemical compounds in order to cause decomposition. In this case pyrolysis causes decomposition of the zinc precursor and the yttrium precursor so that oxidization of the zinc and the yttrium forms yttrium doped zinc oxide. However, excess heat can destroy the underlying electronic device so the temperature needs to be kept in a range that is not destructive to the underlying device. For example, the temperature of the substrate can be between 100 degrees Celsius and 500 degrees Celsius if the substrate is more resilient, such as glass. If the substrate is a semiconductor or other sensitive electronic device the substrate temperature can be between 250 degrees Celsius and 400 degrees Celsius. In particular, the temperature can be approximately 300 degrees Celsius.

The deposition time, along with the zinc concentration in the solution and the flow rate of the solution, determines the thickness of the deposited transparent conducting oxide. For example, the flow rate of the solution can vary between 1 and 1,000 mL per minute. Varying the flow rate can produce a transparent conducting oxide that is between 100 nanometers and 10 micrometers thick. In particular, a transparent conducting oxide can be produced that is approximately 500 nanometers thick.

FIG. 4 also shows that the method 400 can include annealing the transparent conducting oxide film on the substrate 420. In at least one implementation, annealing the film on the substrate 420 includes a controlled environment. Additionally or alternatively, annealing the film on the substrate includes keeping or reheating the film at a high temperature to reduce the resistivity of the film to below 5×10⁻⁴ Ω-cm.

In at least one implementation, annealing the film on the substrate 420 can include annealing the film in the presence of a gas. The gas can either contain oxygen or be oxygen free. For example, air, oxygen, or water-saturated nitrogen can be used as a gas that contains oxygen. Additionally or alternatively, nitrogen or helium can be used as a gas that does not contain oxygen. Additionally or alternatively, the annealing can occur in a vacuum.

In at least one implementation, annealing the film on the substrate 420 can include heating the film created on the substrate in the presence of oxygen, in an oxygen free gas or a vacuum in order to lower the resistivity. In particular, annealing the film on the substrate 420 can cause excess oxygen in the film to be removed, lowering the resistivity of the transparent conducting oxide. For example, the substrate can be heated to between 250 degrees Celsius and 500 degrees Celsius for between 10 minutes and 3 hours in 1 atm nitrogen to lower the resistivity of the transparent conducting oxide.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method for applying a transparent conducting oxide, wherein the method comprises:
providing a solution, wherein the solution includes:
a solvent;
a zinc precursor; and
an yttrium precursor;
spraying the solution on a heated substrate, wherein the heated substrate turns the solution into a yttrium-doped zinc oxide film; and
annealing the film on the substrate in a controlled environment.

2. The method of claim 1, wherein the zinc precursor includes one of:
zinc chloride;
zinc acetate;
zinc nitrate; or
zinc sulfate.

3. The method of claim 1, wherein the yttrium precursor includes one of:
yttrium chloride;
yttrium acetate;
yttrium nitrate; or
yttrium sulfate;

4. The method of claim 1, wherein the temperature of the substrate during spraying is between 100 and 500 degrees Celsius.

5. The method of claim 4, wherein the temperature of the substrate during spraying is between 250 and 400 degrees Celsius.

6. The method of claim 5, wherein the temperature of the substrate during spraying is approximately 300 degrees Celsius.

7. The method of claim 1, wherein the concentration of the yttrium precursor is between 0.1 percent and 15 percent of the concentration of the zinc precursor.

8. The method of claim 1, wherein the concentration of the yttrium precursor is approximately 8 percent of the concentration of the zinc precursor.

9. A semiconductor device, wherein the semiconductor device includes a transparent conducting oxide applied according to the method of claim 1.

10. A method for applying a transparent conducting oxide, wherein the method comprises:
providing a solution, wherein the solution includes:
a solvent;
a zinc precursor; and
an yttrium precursor;
providing a heated substrate, wherein the substrate includes a base layer to which a transparent conducting oxide can be applied;
spraying the solution on the heated substrate, wherein spraying the solution on the substrate includes:
providing a carrier gas;
pressurizing the carrier gas; and
spraying the pressurized carrier gas and the solution onto the substrate,
wherein the carrier gas atomizes the solution;
wherein the heated substrate turns the solution into a yttrium-doped zinc oxide film; and
annealing the film on the substrate in a controlled environment, wherein the controlled environment includes:
heating the film to between 250 and 500 degrees Celsius.

11. The method of claim 10, wherein the carrier gas includes one of:
air; or
nitrogen gas.

12. The method of claim 10, wherein the controlled environment further includes providing a controlled atmosphere, wherein the controlled atmosphere includes one of:
nitrogen;
oxygen; or
a vacuum.

13. The method of claim 12, wherein the annealing the film on the substrate includes annealing the film between 10 minutes and 3 hours.

14. The method of claim 10, wherein the solvent further includes one of:
water;
an acid;
a base; or
an organic.

15. A structure, wherein the structure comprises:
a substrate, wherein the substrate includes a base layer to which a transparent conducting oxide can be applied; and
the transparent conducting oxide, wherein the transparent conducting oxide includes:
a zinc oxide layer; and
an yttrium oxide dopant, wherein the yttrium oxide dopant is within the zinc oxide layer.

16. The structure of claim 0, wherein the transparent conducting oxide is between 100 nanometers and 10 micrometers thick.

17. The structure of claim 16, wherein the transparent conducting oxide is approximately 500 nanometers thick.

18. The structure of claim 0, wherein the resistivity of the transparent conducting oxide is less than 5×10̂−4 Ω-cm.

19. The structure of claim 18, wherein the resistivity of the transparent conducting oxide is between 1×10̂−4 Ω-cm and 3×10̂−4 Ω-cm.

20. The structure of claim 19, wherein the resistivity of the transparent conducting oxide is approximately 2×10̂−4 Ω-cm.
